(19) United States
(12) Patent Application Publication
(10) Pub. No.: US 2025/0112052 A1
(43) Pub. Date: Apr. 3, 2025

(54) DIRECTIONAL RIE FEATURE RECTANGULARITY

(71) Applicant: Applied Materials, Inc., Santa Clara, CA (US)

(72) Inventors: Yi-Hsin CHEN, Bedford, MA (US); Kevin R. Anglin, Somerville, MA (US); Yong Yang, Brookline, MA (US); Solomon Belangedi Basame, Middleton, MA (US); Yung-Chen Lin, Westwood, MA (US); Gang Shu, Hillsboro, OR (US)

(73) Assignee: Applied Materials, Inc., Santa Clara, CA (US)

(21) Appl. No.: 18/478,878

(22) Filed: Sep. 29, 2023

(51) Int. Cl. H01L 21/3065

(52) U.S. Cl. CPC H01L 21/3065

(57) ABSTRACT

Disclosed herein are methods for forming opening ends within semiconductor structures. In some embodiments, a method may include providing an opening formed in a layer of a semiconductor device, wherein the opening comprises a set of sidewalls opposite one another, and first and second end walls connected to the sidewalls, wherein each of the first and second end walls defines a tip end and a set of curved sections extending between the tip end and the set of sidewall. The method may further include performing an ion etch to the opening by delivering an ion beam at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

### FIELD OF THE DISCLOSURE

Embodiments of the present disclosure relate to formation of semiconductor structures. More particularly, embodiments of the present disclosure relate to methods for forming opening ends within semiconductor structures.

### BACKGROUND OF THE DISCLOSURE

Fabrication of advanced three-dimensional (3-D) semiconductor structures with complex surface topology and high packing density is populated with complex technical challenges. Some of these challenges are addressed for metal and dielectrics using directed reactive ion etching (DRIE).

During conventional one-dimensional patterning, such as opening elongation, via hole alignment, or space tip-to-tip push, the shape of the hole or space end may be changed. Pattern corner rounding has been a challenge to pattern fidelity in smaller nodes during the lithography, regardless of wavelength used. For example, there is insufficient resolution for the end of the line made up of two rectangular corners where the isolated line width shows line end shortening, which inevitably generates rounding corners. Existing techniques to improve corner rounding are to utilize optical proximity correction (OPC) with multiple patterning, self-aligned double patterning, and quad-patterning in lithographic process. However, this approach is process intensive and, therefore, more costly and prone to errors.

Improved techniques for shape modification at the end of opening elongations is therefore desirable.

### SUMMARY OF THE DISCLOSURE

This Summary is provided to introduce a selection of concepts in a simplified form that are further described below in the Detailed Description. This Summary is not intended to necessarily identify key features or essential features of the claimed subject matter, nor is it intended as an aid in determining the scope of the claimed subject matter.

In one approach, a method may include providing an elongated opening formed in a layer of a semiconductor device, wherein the elongated opening comprises a set of sidewalls opposite one another, and a first end wall and a second end wall connected to the set of sidewalls, wherein each of the first end wall and the second end wall defines a tip end and a set of curved sections extending between the tip end and the set of sidewall. The method may further include performing an ion etch to the elongated opening, wherein the ion etch comprises an ion beam delivered at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

In another approach, a method of patterning an opening in a semiconductor device may include providing the opening through a layer of the semiconductor device, wherein the opening includes a set of sidewalls extending parallel to one another, and a first end wall and a second end wall connected to the set of sidewalls, wherein each of the first end wall and the second end wall defines a tip end and a set of curved sections extending between the tip end and the set of sidewalls. The method may further include, performing an ion etch to the opening, wherein the ion etch comprises an ion beam delivered towards the first end wall or the second end wall at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

In yet another approach, a method of patterning an opening in a semiconductor device may include providing the opening formed through a layer of the semiconductor device, wherein the opening comprises a set of sidewalls extending parallel to one another, and a first end wall and a second end wall connected to the set of sidewalls, wherein each of the first end wall and the second end wall defines a tip end and a set of curved sections extending between the tip end and the set of sidewalls. The method may further include performing an ion etch to the opening, wherein the ion etch comprises an ion beam delivered towards the first end wall or the second end wall at a non-zero angle relative to a perpendicular extending from a plane defined by a top surface of the layer of the semiconductor device, wherein the ion etch comprises a lean-gas chemistry, and wherein the ion etch causes a quarter tip curvature of the first end wall or the second end wall to decrease.

### BRIEF DESCRIPTION OF THE DRAWINGS

The accompanying drawings illustrate exemplary approaches of the disclosure, including the practical application of the principles thereof, as follows:

FIG. 1 is a top view of an opening of a layer of a semiconductor device, according to embodiments of the present disclosure;

FIG. 2 is a top view of the opening of the layer of the semiconductor device following an etch process, according to embodiments of the present disclosure;

FIG. 3A is a top view of a plurality of openings of a layer of a semiconductor device, according to embodiments of the present disclosure;

FIG. 3B is a top view of the plurality of openings of the layer of the semiconductor device following an etch process, according to embodiments of the present disclosure;

FIGS. 4-7 demonstrate an ion etch process to an opening, according to embodiments of the present disclosure;

FIG. 8 is a graph showing a relationship between sputter angle and sputter yield, which correlates with RIE etch rate, according to embodiments of the present disclosure;

FIGS. 9-10 are graphs showing angular and spatial sputter rates for an etch process, according to embodiments of the present disclosure;

FIG. 11 is a block diagram showing factors that influence final opening profile, according to embodiments of the present disclosure;

FIG. 12 is a graph showing tip profiles after sputtering, according to embodiments of the present disclosure;

FIGS. 13A-13D demonstrate use of quarter tip curvature to quantity improvement of corner rounding following etching, according to embodiments of the present disclosure; and

FIG. 14 is a process flow for forming elongated openings in a semiconductor device in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments herein enable modifying feature rectangularity in hole patterns by using specific hardware and process control. Creating sharper, rectangular corners in hole patterns benefits precise critical dimension (CD) control and pattern fidelity of features during semiconductor manufacturing. To improve corner rounding of an opening, embodiments herein advantageously incorporate a directional RIE process, for example, an ion beam at an angle of 50˜60°, together with a lean gas chemistry to facilitate more ion etch, instead of radical etch. Advantageously, sputter yield of a certain material can be optimized with a specific ion species, energy, and incidence angle.

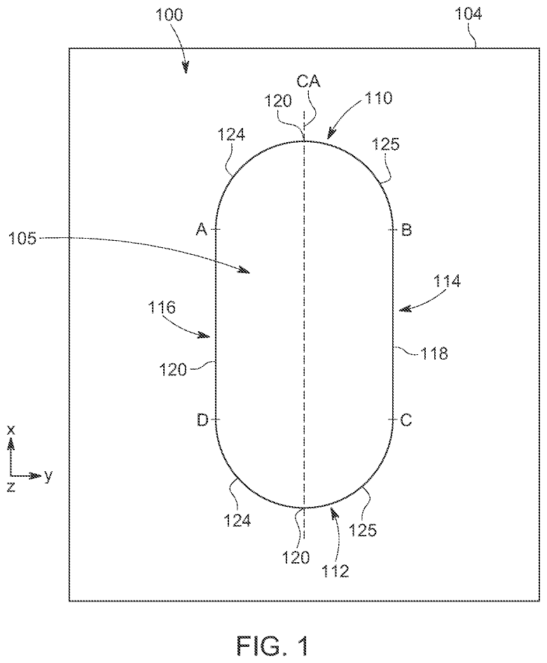

FIG. 1 demonstrates an opening 105 in a layer 104 of a device 100, such as a semiconductor device, according to embodiments of the present disclosure. The opening 105 may be an elongated opening defined generally by a first end wall 110, a second end wall 112, and a set of sidewalls 114, 116 connected with the first end wall 110 and the second end wall 112. In some embodiments, the sidewalls 114, 116 may include one or more square-shaped sections 118, 120 extending parallel to one another.

The first end wall 110 may extend between points ‘A’ and ‘B’ along the perimeter of the opening 105, while the second end wall 112 may extend between points ‘C’ and ‘D’ along the perimeter of the opening 105. Points A-D correspond to locations along the perimeter of the opening 105 where the sidewall(s) begins to curve towards respective tip ends 120 of the first end wall 110 and the second end wall 112. Between points A and D the sidewall 116 is generally straight or flat, and between points C and D the sidewall 118 is also generally straight or flat. Furthermore, each of the first and second end walls 110, 112 may be defined by a set of curved sections 124, 125 extending between the tip end 120 and the set of sidewalls 114, 116. Said another way, curved section 124 may extend between point A and a central axis ‘CA’, while curved section 125 may extend between point B and the central axis. As shown, the central axis may correspond to a straight line extending between the tip end 120 of the first end wall 110 the tip end 120 of the second end wall 112. In some embodiments, the first and second end walls 110, 112 are generally symmetrical, while in other embodiments, the first and second end walls 110, 112 may not be symmetrical.

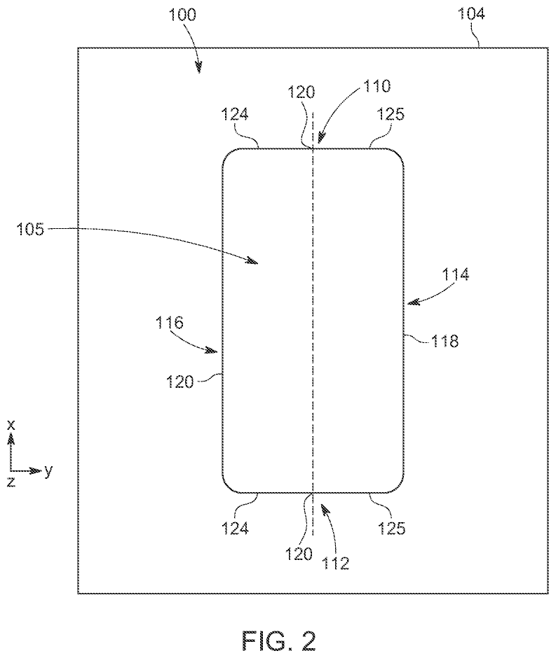

It may be desirable to have a generally flatter tip end 120 and square, wide curved sections 124, 125. To accomplish this, the device 100 is subjected to an etch process, e.g., a directional reactive ion etch (RIE), which includes delivering an ion beam to the sidewalls of the opening 105 to cause the curved sections 124, 125 to be removed faster than the sidewalls 116, 118. The curved sections 124, 125 may also to be removed faster than at the tip ends 120. The etch process may further involve a specific gas type, e.g., lean gas chemistry (non-polymerizing), which may include argon, krypton and/or xenon in some non-limiting examples. Following the etch process, the curved sections 124, 125 of the first end wall 110 and/or the second end wall 112 are “squared off,” as depicted in FIG. 2.

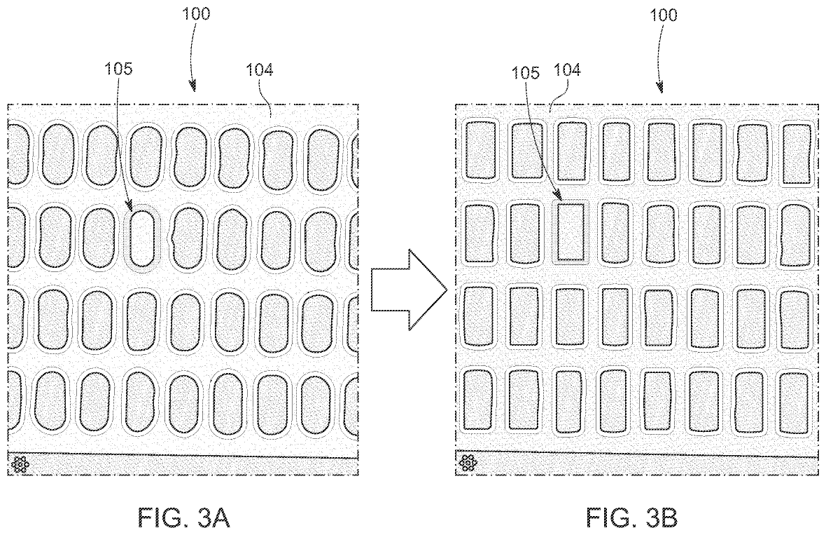

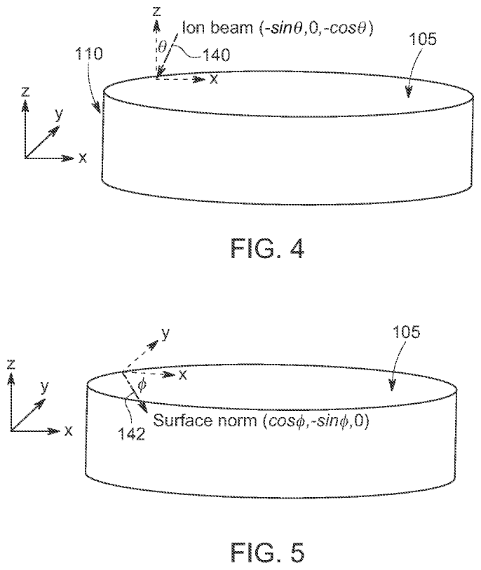

This process is again demonstrated on a relatively larger scale in FIGS. 3A-3B, wherein FIG. 3A shows a plurality of openings 105 formed in a layer 104 of a device 100 prior to the etch process, and FIG. 3A shows the plurality of openings 105 in the layer 104 of the device 100 following the etch process. As shown, each end or tip of the openings 105 is transformed from a curved, circular, or oval shape, to a rectangular shape including corners that are closer to 90°.

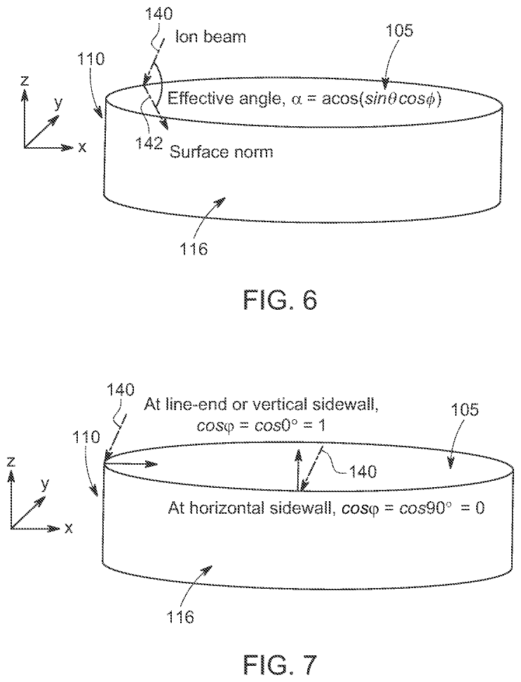

Turning to FIGS. 4-7, the ion etch process to the opening 105 will be described in greater detail. The ion etch includes an ion beam 140 delivered at a non-zero angle (θ) relative to a perpendicular (e.g., z-axis) extending from an upper surface of the layer 104 of the semiconductor device 100. In other embodiments, the ion beam 140 may be directed at the opening 105 to form a treated layer along the sidewall of the opening 105. The angled ion beam 140 may impact all or just a portion of the sidewall of the opening 105 between the top surface of the layer 104 and a bottom surface of the layer 104.

As best shown in FIG. 4, the ion beam 140 is defined as a vector hitting the side wall (e.g., first end wall 110) in the xz plane (y=0). On some platforms, θ can be controlled with ion energy, RF power, and/or z-gap. The ion beam 140 and the opening 105 sidewalls further define a surface normal vector 142 and a structure surface norm angle, ϕ. As best shown in FIG. 5, the surface normal vector 142 is defined as the vector normal to the sidewall in the xy plane (x=0), while FIG. 6 demonstrates the effective angle α=acos(sinθ cosϕ) between the ion beam 140 and the surface normal vector 142.

A flux factor is defined as cosα, wherein α is the effective incident angle between the ion beam 140 and the surface normal vector 142. As best demonstrated in FIG. 7, when α reaches 0, the sidewall receives maximum exposure to the ion beam 140 (cosα=1). When α reaches 90, the sidewall receives no exposure (cosα=0). A max flux factor can be calculated as sinθcosϕ. Note α=acossinθcosϕ, where θ is the beam angle andϕ is the normal angle to the x-axis. During the etch process, ion beam angle θ remains the same but ϕ changes along the sidewall, e.g., between the first end wall 110 and the sidewalls 116, 118.

To demonstrate, in one non-limiting example, at the first end wall 110 the flux % may be approximately 76%, and the effective angle may be approximately 40°, wherein cosφ=cos0°=1, sinθ=sin50°=0.76, and acossinθ cosϕ=40°. Meanwhile, closer to the horizontal sidewalls 116, 118, the flux % may be approximately 1.7%, and the effective angle may be approximately 89°, wherein cosφ=cos89°=0.017, sinθ=sin50°=0.76, and acossinθ cosϕ=89°.

Sputter yield is another important consideration of the etch process. The sputter yield of a certain material can be optimized with a specific ion species, energy, and incidence angle. The dependencies of different materials vary in multi-dimensional space, and thus it is feasible to choose specific conditions as to select the desired ratio of sputter yields between multiple materials. For example, a high sputter yield at certain range of beam angles facilitates good carbon etch selectivity.

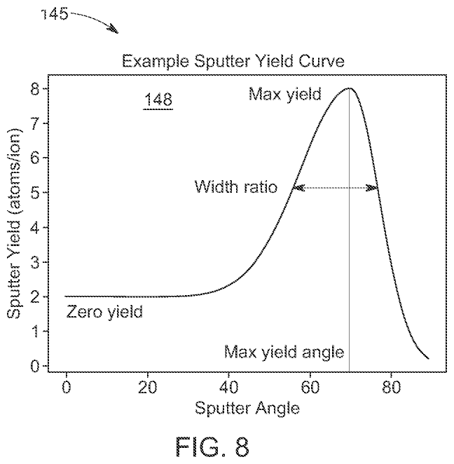

FIG. 8 is a graph 148 showing the relation between sputter angle and sputter yield, which correlates with RIE etch rate. Sputtering of atoms from a substrate is the result of the physical collision between energetic ions, typically >100 eV, and atoms in the substrate lattice, which are dislocated and ejected as a result of the collisions. RIE also depends on ion collisions, causing lattice dislocations, to provide reactive sites for the chemical reactions that drive reactive ion etching. Therefore, the RIE etch rate depends on the sputter angle in a manner similar to the curve shown in graph 148. In this non-limiting example, a dual Gaussian curve may be used to approximate the line shape. Here, the zero yield may be 1 or 2, the max yield angle may be 55, 60, 70, etc., the max yield may be 1.2, 4, 8, and the width ratio may be ⅓, ¼, ⅕. Embodiments herein are not limited in this context, however.

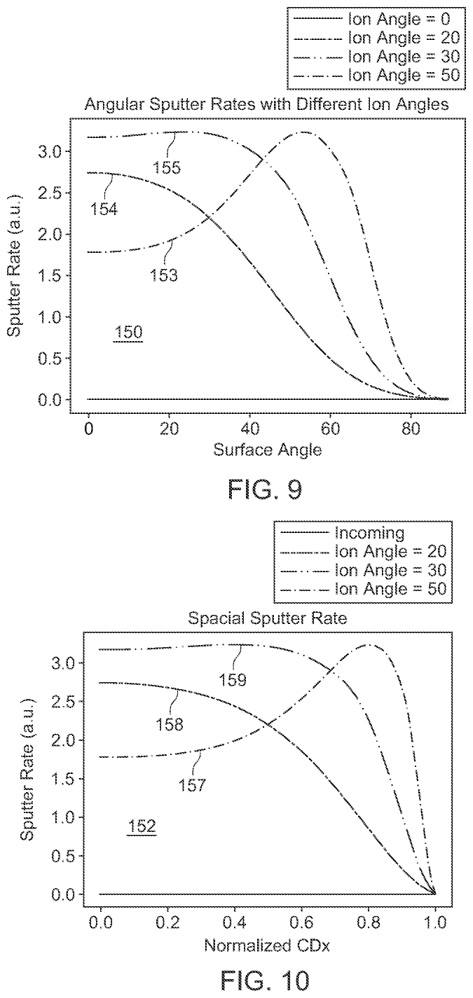

Angular and spatial sputter rates for the etch process may also vary, as demonstrated by graph 150 of FIG. 9 and graph 152 of FIG. 10, respectively. More specifically, the relationship between sputter rate, surface angle, and ion beam angle is shown by curves 153, 154, and 155 in FIG. 9. For example, the sputter rate of curve 153 (i.e., ion angle of 50°) increases until approximately 55°, after which it decreases. Curve 154, however, only ever decreases. In FIG. 10, the relationship between sputter rate, normalized CDₓ, and ion beam angle is shown by curves 157, 158, and 159. As demonstrated, the spatial sputter rate pushes the peak to the edge.

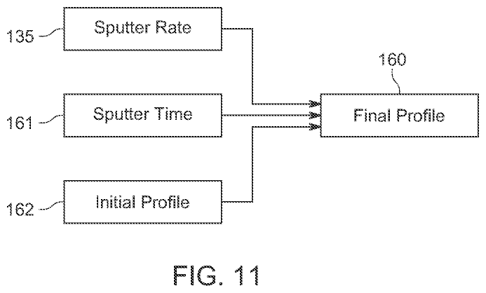

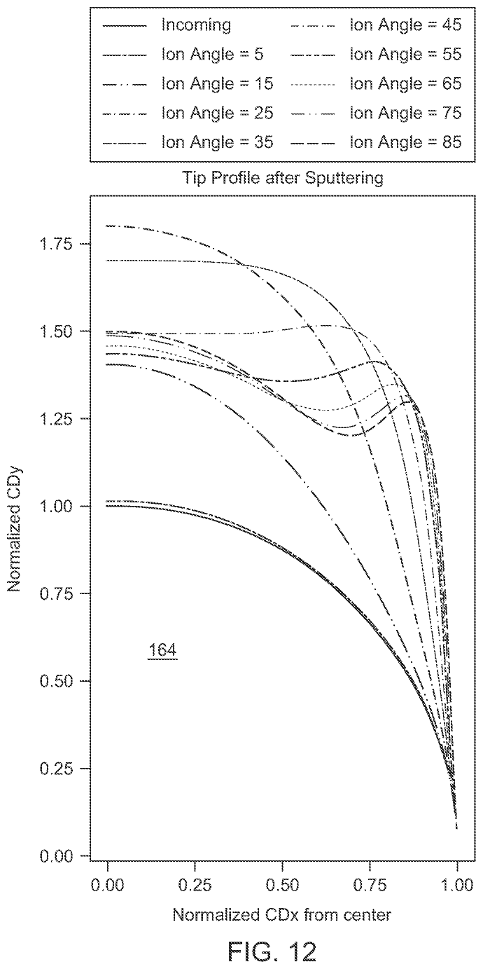

FIG. 11 very generally demonstrates that the final profile (e.g., rectangle) of the opening 105 depends upon the sputter rate 135, a selected sputter time 161, and an initial profile 162 of the opening 105. Graph 164 of FIG. 12 demonstrates in more detail the tip profile after sputtering in terms of Normalized CDy vs. Normalized CDx from center. To demonstrate, in one example, the following assumptions are made for the yield curve: zero yield=2, max yield angle=70, max yield=8, and width ratio=¼. It is also assumed that the end of the opening initially has a perfect semicircular shape. Following the etching, the curves corresponding to ion angles 45 and 55, for example, demonstrate the most rectangular corner profile.

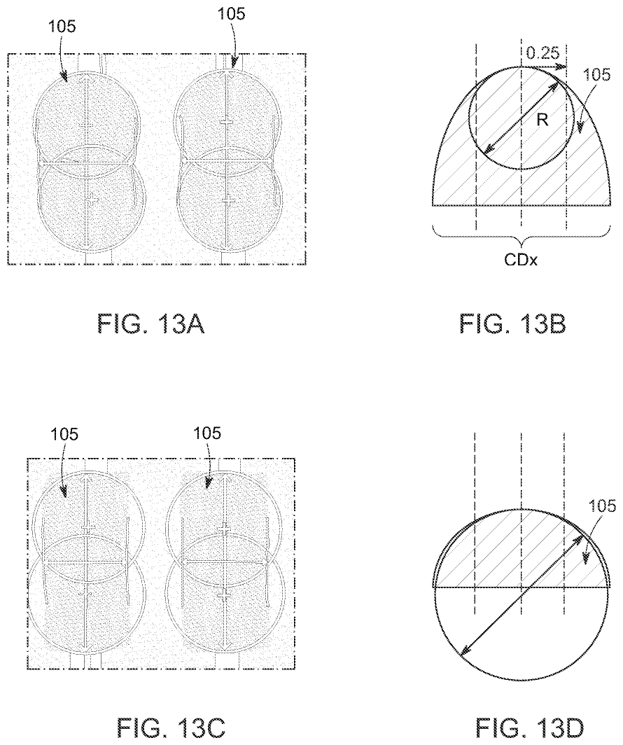

Referring to FIGS. 13A-13D, quarter tip curvature is used to quantity the improvement of corner rounding following the etch process. FIGS. 13A and 13B represent the opening 105 before etching, while FIGS. 13C and 13D represent the opening 105 after etching. Quarter tip curvature is defined as CDₓ divided by the diameter of curvature circle at quarter tip (i.e., QuarterRadius=CDₓ/R). As shown, the rounded end has a smaller diameter and thus it has higher quarter tip curvature value. Following the etch process, the curvature value decreases.

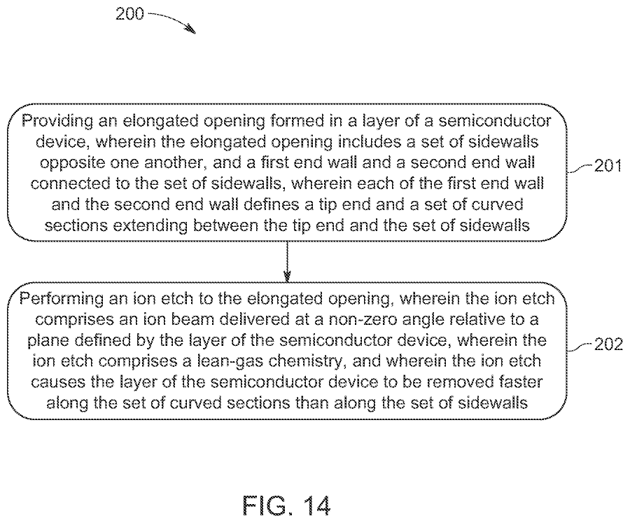

Turning now to FIG. 14, a method 200 of forming an opening in a semiconductor device will be described. At block 201, the method 200 may include providing an elongated opening formed in a layer of a semiconductor device, wherein the elongated opening includes a set of sidewalls opposite one another, and a first end wall and a second end wall connected to the set of sidewalls, wherein each of the first end wall and the second end wall defines a tip end and a set of curved sections extending between the tip end and the set of sidewalls.

At block 202, the method 200 may further include performing an ion etch to the elongated opening, wherein the ion etch comprises an ion beam delivered at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

In some embodiments, the ion etch causes the tip end to be squared. In some embodiments, the lean-gas chemistry includes at least one of: argon, and oxygen. In some embodiments, the non-zero angle of the ion beam is between 50° and 60°. In some embodiments, performing the ion etch to the elongated opening includes directing the ion beam towards the first end wall, the second end wall, and the set of sidewalls, and wherein an ion flux is optimized at the first and second end walls. In some embodiments, at least one of the first end wall and the second end wall has a curved profile, such as a semicircular profile. In some embodiments, the ion beam defines an effective incident angle between the ion beam and a surface normal vector, and wherein the effective incident angle is greater along the set of sidewalls than along the first end wall and the second end wall.

In sum, embodiments herein may be used to address CD control by improving the corner rounding issue. Embodiments herein may represent an alternative and economic solution to the existing techniques utilizing optical proximity correction (OPC) with multiple patterning, self-aligned double patterning, and quad-patterning in lithographic processes.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the device 100, e.g., as described herein. For example, data sets can be created to perform the etch process described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing an elongated opening formed in a layer of a semiconductor device, wherein the elongated opening comprises:
a set of sidewalls opposite one another; and
a first end wall and a second end wall connected to the set of sidewalls, wherein each of the first end wall and the second end wall defines a tip end and a set of curved sections extending between the tip end and the set of sidewalls; and
performing an ion etch to the elongated opening, wherein the ion etch comprises an ion beam delivered at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

2. The method of claim 1, wherein the ion etch causes the tip end to be square-shaped.

3. The method of claim 1, wherein the lean-gas chemistry comprises at least one of:
argon, krypton, and xenon.

4. The method of claim 1, wherein the non-zero angle of the ion beam is between 40° and 80° with respect to normal incidence to the plane defined by the layer of the semiconductor device.

5. The method of claim 1, wherein performing the ion etch to the elongated opening comprises directing the ion beam towards the first end wall and the second end wall only, and wherein an ion flux is optimized at the first end wall and the second end wall.

6. The method of claim 1, wherein at least one of the first end wall and the second end wall has a curved profile.

7. The method of claim 1, wherein at least one of the first end wall and the second end wall has a semicircular profile.

8. The method of claim 1, wherein the ion beam defines an effective incident angle between the ion beam and a surface normal vector, and wherein the effective incident angle is greater along the set of sidewalls than along the first end wall and the second end wall.

9. The method of claim 1, wherein the non-zero angle of the ion beam is constant during the ion etch.

10. A method of patterning an opening in a semiconductor device, comprising:
providing the opening through a layer of the semiconductor device, wherein the opening comprises:
a set of sidewalls extending parallel to one another; and
a first end wall and a second end wall connected to the set of sidewalls,
wherein each of the first end wall and the second end wall defines a tip end and a set of curved sections extending between the tip end and the set of sidewalls; and
performing an ion etch to the opening, wherein the ion etch comprises an ion beam delivered towards the first end wall or the second end wall at a non-zero angle relative to a plane defined by the layer of the semiconductor device, wherein the ion etch comprises a lean-gas chemistry, and wherein the ion etch causes the layer of the semiconductor device to be removed faster along the set of curved sections than along the set of sidewalls.

11. The method of claim 10, wherein the ion etch causes the tip end to be square-shaped, and wherein the tip end is perpendicular to the set of sidewalls.

12. The method of claim 10, wherein the lean-gas chemistry comprises at least one of:
argon, krypton, and xenon.

13. The method of claim 10, wherein the non-zero angle of the ion beam is between 40° and 80° with respect to normal incidence to the plane defined by the layer of the semiconductor device.

14. The method of claim 10, wherein performing the ion etch to the opening comprises directing the ion beam towards the first and second end walls only, and wherein an ion flux is optimized at the first and second end walls.

15. The method of claim 10, wherein at least one of the first end wall and the second end wall has a curved profile.

16. The method of claim 10, wherein the non-zero angle of the ion beam is constant during the ion etch, wherein the ion beam defines an effective incident angle between the ion beam and a surface normal vector, and wherein the effective incident angle is greater along the set of sidewalls than along the first end wall and the second end wall.

17. A method of patterning an opening in a semiconductor device, comprising:
providing the opening formed through a layer of the semiconductor device, wherein the opening comprises:
a set of sidewalls extending parallel to one another; and
a first end wall and a second end wall connected to the set of sidewalls,
wherein each of the first end wall and the second end wall defines a tip end and a set of curved sections extending between the tip end and the set of sidewalls; and
performing an ion etch to the opening, wherein the ion etch comprises an ion beam delivered towards the first end wall or the second end wall at a non-zero angle relative to a perpendicular extending from a plane defined by a top surface of the layer of the semiconductor device, wherein the ion etch comprises a lean-gas chemistry, and wherein the ion etch causes a quarter tip curvature of the first end wall or the second end wall to decrease.

18. The method of claim 17, wherein the ion etch causes the tip end to square-shaped.

19. The method of claim 17, wherein performing the ion etch to the opening comprises directing the ion beam towards the first end wall and the second end wall only, and wherein an ion flux is optimized at the first and second end walls.

20. The method of claim 17, wherein the lean-gas chemistry comprises at least one of:
argon, krypton, and xenon, and wherein the non-zero angle of the ion beam is between 40° and 80° with respect to the perpendicular extending from the plane defined by the top surface of the layer of the semiconductor device.
